(19) United States
(12) Patent Application Publication
(10) Pub. No.: US 2024/0162002 A1
(43) Pub. Date: May 16, 2024

(54) FAST FRAMING ELECTRON DETECTOR FOR 4D-STEM

(71) Applicant: DECTRIS AG, Baden-Dättwil (CH)

(72) Inventors: Michael RISSI, Baden-Dättwil (CH); Roland HORISBERGER, Baden-Dättwil (CH); Roger SCHNYDER, Baden-Dättwil (CH); Alfonso Gonzalez Taboada, Baden-Dättwil (CH)

(73) Assignee: DECTRIS AG, Baden-Dättwil (CH)

(21) Appl. No.: 18/549,028

(22) PCT Filed: Mar. 5, 2021
(86) PCT No.: PCT/EP2021/055689

§ 371 Date: Sep. 5, 2023

(51) Int. Cl. H01J 37/244; H01J 37/28

(52) U.S. Cl. CPC H01J 37/244; H01J 37/28

(57) ABSTRACT

A radiation detector for position-resolved detection of radiation comprises at least one sensor tile with a front side facing incident radiation, and a back side opposite the front side. The sensor tile comprises a sensor material sensitive to the radiation. A front electrode is arranged on the front side of the sensor tile. A braking layer is arranged on the front electrode and at least partly covers the front electrode, for decelerating electrons in the incident radiation. A set of contacts of electrically conducting material is arranged on the back side of the sensor tile and in contact with the sensor material, thereby defining sensor pixels. At least one ASIC comprises a set of readout circuits in electrical connection with the contacts, each readout circuit being configured to process a signal received from the sensor pixel the readout circuit is electrically connected to. Each readout circuit of the set is configured to provide an output signal representative of the radiation incident in the corresponding sensor pixel.

### TECHNICAL FIELD

The present invention refers to a radiation detector and to a method of manufacturing a radiation detector.

### BACKGROUND ART

Direct-converting pixel detectors become more and more popular for many reasons. A direct converting detector is understood as a detector for directly converting incident radiation into electrical charges without intermediary conversion. Suitable sensor material for a direct converting detector may be Si, for example. A pixel detector is understood as a device that collects signals from many adjacent pixels which in combination define an active sensor area. Accordingly, a spatial resolution can be achieved by such direct-converting pixel detector. Typically, such detector comprises a sensor tile of the sensor material in a planar dimension. Electrical contacts in form of e.g. metallizations or e.g. ion implants are formed on the back side of the sensor tile and are in contact with the sensor material. These contacts, electrically isolated from each other, define pixels of the sensor tile given that each contact collects and leads off electrical charges generated in the portion/volume of the contacted sensor material after its interaction with the incoming radiation/ionizing particle.

An ionizing particle hitting the sensor tile generates a charge signal induced in the sensor pixels. The multitude of sensor pixels finally provide a 2D image of incident radiation, i.e. a distribution of radiation across the area of the sensor tile. A totality of the pixel signals for a given point in time defines an intensity image, which is also referred to as frame.

Such detectors may in particular be useful in electron scanning applications. Some of these applications require detectors able to operate at extremely high frame rates. This is especially true for 4D STEM. TEM stands for Transmission Electron Microscopy and, hence, for radiating a thin sample with an electrode beam and collecting the transmitted or scattered portions of the electron beam. Valuable information can be collected by means of the TEM scanning mode, in which the electron beam scans the sample of interest and electrons transmitted or scattered are detected and analysed. Assuming that the sample is scanned in 2D coordinates, per each scanned coordinate a 2D image is detected and processed. In other words, a 2D electron image (2D detector frame) is recorded for each point of a 2D scan of the sample with the electron beam. This leads to the term “4D STEM”.

However, the characteristic low frame rate of commercially available detectors limits their application to high electron flux TEM. The electrons in a STEM with typical energies above 200 keV up to 400 keV can cause displacement of atoms in the sensor material from their original lattice position. The induced crystal defects in the sensor tile may degrade the charge transport properties of the semiconductor material of the sensor, and thus may degrade the performance of the detector. The higher the energy, the higher the probability of displacing an atom in the lattice. If the number of electrons impinging the sensor per time unit increases, i.e. the electron flux is enhanced, the probability of lattice atom displacement events increases as well. The interaction of electrons of 200 keV-400 keV energy in silicon inhibits increasing the spatial resolution of the detector given that the electrons have long scatter lengths. In other words, pixel sizes below 150 μm do not increase the spatial resolution of Si sensors excited with electron beams with energy above 200 keV.

Hence, it is desired to avoid one or more of the drawbacks associated with the prior art.

### DISCLOSURE OF THE INVENTION

The problem is solved by a radiation detector for position-resolved detection of radiation. The detector comprises at least one sensor tile with a front side facing incident radiation, and a back side opposite the front side. The sensor tile comprises or is made from a sensor material sensitive to the radiation to be detected. A front electrode is arranged on the front side of the sensor tile while a set of contacts is arranged on the back side of the sensor tile and is in contact with the sensor material thereby defining sensor pixels. At least one ASIC comprises a set of readout circuits in electrical connection with the contacts, each readout circuit being configured to process a signal received from the sensor pixel the readout circuit is electrically connected to and being configured to provide an output signal representative of the radiation incident in the corresponding sensor pixel, which output signal preferably represents the processed signal.

Accordingly, the radiation detector preferably is a hybrid pixel detector (HPD) for high-flux detection in x-ray, EM and/or STEM systems operating with high electron beam current or high x-ray flux. In particular for applications in 4D STEM, in which a focused electron beam is scanned over a sample, such HPD offers significant advantages. It can in particular be used for measuring electrons per pixel, and hence provide a 2D image for the scattered and transmitted electrons per each scanned sample point.

In (S)TEM, but also in other electron microscopy applications, electrons are highly energized and e.g. accelerated with voltages typically between 200 kV and 300 kV, such that kinetic energies between 200 keV and 300 keV can be reached. Such electrons have long scatter lengths in the sensor material, which inhibits increasing the spatial resolution of the detector, possibly limiting a pixel size to about ˜150 μm in the case of a silicon sensor material.

The electron beam may reach currents as high as several nA while impinging the sensor material.

Therefore, means are provided in the sensor element to decrease energy of electrons before hitting the sensor material, i.e. before hitting the sensor tile. Such means prevent e.g. such high-energy electrons with an energy between e.g. 200 keV and 400 keV, in particular present in STEM applications, to displace atoms from their place in the semiconductor crystal lattice of the sensor tile, thereby degrading sensor performance. Accordingly, such means can be described as braking means configured to decelerate the electrons and hence decreasing the energy of the electrons before hitting the sensor material. Such braking means may also be suited to decrease the flux for incident radiation and may also be suited for other incident radiation, such as x-rays.

The braking means include a braking layer arranged on the front electrode. It is envisaged that incident electrons transit the braking layer thereby loosing energy, then transiting the front electrode and entering the sensor material at reduced energy compared to the energy at which the braking layer is hit.

The braking layer does not necessarily cover the entire front electrode, although in one preferred embodiment it may do so. At least a part of the front electrode is covered by the braking layer. A partial coverage of the braking layer may be an advantage e.g. in case the electron flux on the sensor is expected to be high in a certain area of the sensor, e.g. where the direct electron beam hits the sensor. In addition, in case of only a part of the front electrode being covered, a bias voltage connection can preferably be directly applied to the front electrode, preferably to its uncovered area, by means e.g. of a low resistivity wire bond, cable or wire. However, in a different embodiment of the partly covered front electrode, the bias voltage connection is applied to, i.e. connected to, the braking layer. This implies an electrically conducting braking layer and an electrically conductive path between the braking layer and the front electrode.

In a very preferred embodiment, the area of the front electrode covered by the braking layer is at is least 10×10 sensor pixels, or is at least 5 mm². Preferably, in combination with such minimum coverage the braking layer is dimensioned smaller than the front electrode. Accordingly, not the entire area of the front electrode is covered by the braking layer. Preferably, the front electrode covers the entire sensor tile.

Preferably, a material of the braking layer is selected such that inelastic scattering of incident electrons—i.e. the incoming electrons lose energy—prevails over elastic scattering—i.e. the incoming electrons only change direction, which leads to a reduction of spatial resolution of the detector.

Therefore, it is preferred that scattering interactions of the incident electrons occur with the electrons in the braking layer's material, such that energy of the incident electrons is efficiently transferred, instead of with nuclei, where only a small fraction of the incident electron's energy is transferred. This is the case for low-Z materials. Hence, incoming electrons will mostly interact with electrons of the material in the braking layer by inelastic scattering and thus will loose energy. Accordingly, the braking layer comprises or is made from a low-Z material. A low-Z material is considered as a material with an atomic number of Z<23. The braking layer may in one embodiment consist of a single element material with Z<23. In a different embodiment, the braking layer may be made from multi-element materials, or from compound materials with a low weight-averaged atomic number of Z<23.

In addition, it is preferred that a thickness of the braking layer is dimensioned such that the desired braking effect can be achieved, while on the other hand electrons are desired to reach the sensor material and generate a signal therein. Therefore, in a preferred embodiment, a thickness of the braking layer is above 5 μm, or above 10 μm, or above 15 μm, or above 20 μm, or above 50 μm, or above 100 μm, or above 200 μm.

Preferred low-Z materials may include one or more of the following:
organic compounds, e.g. epoxy based materials, photoresists like SU8, or paraffins, each with a low average Z value,
beryllium,
materials built up from carbon e.g. diamond, diamond-like carbon (DLC), graphite, carbon nanotubes, glassy carbon
aluminium and aluminium-based alloys
organic compounds, such as polyethylene terephthalate (PET), biaxially-oriented polyethylene terephthalate (BoPET) known as Mylar, polytetrafluoroethylene (PTFE) known as Teflon
quartz (SiO2)
boron carbide (B4C)

On one embodiment, the braking layer is arranged on the front electrode, and preferably is directly deposited on the front electrode without any intermediary layer. In such embodiment, the material of the braking layer may especially comprise or consist of e.g. aluminum, and the thickness may be one of above 5 μm, or above 10 μm, or above 15 μm, or above 20 μm, or above 50 μm.

In a different embodiment, an intermediate layer such as an adhesive may be used to attach the braking layer—preferably in form of a sheet—to the front electrode. In such embodiment, the material of the braking layer may comprise or consist of e.g. Be, Al, an organic compound, with a thickness of preferably above 10 μm, 50 μm, 100 μm or 200 μm.

In a preferred embodiment, the braking layer is made from an electrically conductive material, and the braking layer and the front electrode are electrically connected. In such situation, a bias voltage for the front electrode may be applied via the braking layer. Accordingly, a low resistivity wire bond, cable, conductive connector or wire preferably is attached to the braking layer. In a similar way, and in case a conductive adhesive layer is used for attaching the braking layer to the front electrode, the bias voltage may be applied to the front electrode via the adhesive. Accordingly, a low resistivity wire bond, cable or wire preferably is attached to the adhesive. In a different embodiment, a conductive adhesive layer extending out from the assembly of sensor and braking layer is used to establish the bias voltage connection.

In a preferred embodiment, the braking layer is made from the same material as the front electrode. Hence, it is preferred that the front electrode and the braking layer are applied in a common manufacturing step, and, hence, by the same manufacturing process. A combined thickness of the braking layer and the front electrode preferably is at least 5 μm.

In one embodiment, the combined thickness is uniform across the entire sensor tile and meets this thickness requirement. In a different embodiment, a thickness of the combined braking layer and front electrode is not uniform but varies across the area of the sensor tile. In a first embodiment, such thickness is at least 5 μm in a partial area of at least 10×10 sensor pixels, or at least 5 mm², but not in the total area of the sensor tile. Only in this limited area a significant braking effect may be achieved, while outside this limited area the thickness is smaller and a lower or even no significant braking effect may be achieved owed to the reduced thickness. In particular, outside this limited area of increased thickness, the deposited material may be regarded as front electrode only, in particular if its thickness is less than 1 μm as is usual for conventional front electrodes.

In a preferred embodiment, the sensor tile is made from a material with a high atomic number Z. For compound or mixed materials, the atomic Z value is derived by calculating the mass-averaged Z value of the material's atoms. The high electron density in such high-Z sensor materials leads to many interactions of the incident electron with the electrons of the sensor material, therefore shortening the scatter length of the incident electrons inside the sensor. A high-Z material is considered as a material with an atomic number of Z>30. The sensor tile may in one embodiment consist of a single element material with Z>30. In a different embodiment, the sensor tile may be made from multi-element materials, or from compound materials with a high weight-averaged atomic number of Z>30. In particular the sensor tile comprises or consists of one of germanium (Ge), gallium arsenide (GaAs), cadmium telluride (CdTe), cadmium zinc telluride (CZT), mercury iodide (Hg₂I), perovskites or a combination thereof. This choice of material/s has the advantage that the incoming electrons create shorter tracks than e.g. in silicon, which allows the detector to have smaller pixels, in particular smaller than 150 μm, and hence a resolution smaller than 150 μm and achieve a narrower point-spread function.

Preferably, a readout circuit of the ASIC is also referred to as readout pixel, given that typically, one readout circuit is assigned to one sensor pixel. Such readout pixel may include a contact to receive the charge from the sensor pixel via some electrical connection, e.g. a bump bond. In addition, the readout pixel preferably comprises a comparator, also referred to as discrimination stage. In this comparator, the charge signal from the sensor pixel, e.g. after being converted into an analogue voltage pulse by means of an amplifier stage, is compared to a threshold voltage, which threshold, hence, can be interpreted as a level of energy required to represent an X-ray or an electron, for example. It is preferred that the amplifier stage is configured to create very short pulses with a FWHM pulse duration advantageously chosen to be shorter than 40 ns, 20 ns or 10 ns for coping with a high incoming electron rate. An output of the comparator provides a digital pulse as long as the analogue voltage pulse exceeds the threshold. Finally, in one embodiment, the digital pulses are counted in a counter of the readout pixel.

Alternatively, the readout circuit assigned to a sensor pixel may comprise an integrating circuit, where the incident charge is integrated during an exposure time and is stored as analog signal or is converted to and stored as digital signal within the readout pixel until read out. The readout circuit may also represent a mixture of the two modes described above, where the charge is integrated up to a predefined value, then reset, while continuing to integrate further. The number of resets are stored in a counter. During readout, the counter value as well as the remaining stored charge is read out.

Preferably, a threshold generation unit is provided in the readout circuit of each ASIC pixel, which may set or adjust the threshold for the discrimination unit e.g. dependent from a global voltage applied to the ASIC combined with an individual trimming of the pixel. The trimming preferably is performed by a trimming circuit. In a preferred method for trimming the threshold, it is suggested to produce quasi-monochromatic x-rays by illuminating a target sample with polychromatic x-rays from an x-ray tube. The target sample will emit x-rays with a characteristic energy, e.g. by means of exciting and de-exciting electrons from its L or K-shells. The quasi-monochromatic x-rays hitting the sensor element will create a signal with intensity corresponding to the incident x-ray energy. The thresholds in the HPD pixels can thus be set to correspond to this energy, or to an is energy interpolated between two characteristic x-ray energies from two target samples. Accordingly, x-rays can be used to calibrate the detector, which is a much easier procedure than using electrons.

In an embodiment, the discrimination unit is configured to operate with multiple thresholds. E.g. a comparison with a second or further thresholds per pixel may provide spectral information given that only particles with an energy above the threshold/s will be counted. This is especially useful for a spectral X-ray/electron detector. An additional feature of the spectral detector is its ability to detect and measure pulse pile up generated by multiple simultaneous detection events and allowing to interpret such events appropriately during data processing.

In case of the readout circuit comprises a counter, a retrigger unit is preferably used in the readout pixel to prevent counting paralyzation due to pulse pile-up at high rates. Preferably, an output of the discrimination stage is input to the retrigger unit. A retrigger unit is described in WO 2013/017425 A1 which is incorporated by reference. The retrigger unit detects pulses longer than a retrigger duration, and resets the discrimination unit to generate a new pulse provided the input signal is still above the threshold. An adjustable retrigger duration is advantageously matched to the analog voltage pulse duration, or to be slightly longer, and preferably set to a value preferably between 5 ns-500 ns, and particularly is slightly longer by e.g. 2 ns, 5 ns, 10 ns or 20 ns longer than the analog pulse duration. Hence, instant retrigger technology re-evaluates the pulse signal after a predetermined retrigger duration after each count and potentially retriggers the counting circuit in case of a pulse pile-up. The retrigger stage preferably can be disabled or enabled by the user.

The counter is provided for counting the pulses supplied by the discrimination stage or the retrigger unit respectively. The counter accordingly counts digital pulses over time, and preferably is read out after a defined time. The readout counter value preferably is a measure for the X-ray photons or electrons detected by the corresponding sensor pixel in the sensor tile during the defined time.

Pulses are counted per pixel in the counter assigned to the pixel. This mode is referred to as normal mode. However, it is preferred to at least additionally implement a different mode referred to as common counting. In such common counting mode, the pulses of more than one pixel, i.e. a set of N pixels with N>1, also referred to as cluster, are accumulated over a defined interval. In particular in case the individual counters are switched off, possibly except for one pixel counter in the cluster used as common counter, a higher rate than the standard frame rate can be achieved, however, at the cost of a lower spatial resolution, since the spatial resolution is defined by the cluster rather than the individual pixel. In the normal mode, instead, a lower frame rate is achieved at a higher spatial resolution.

A reason for a common counter for a pixel cluster may lie in an enormous frame rate of up to several hundreds of kHz for fast electron-beam scanning allowing to acquire STEM images at high temporal and/or spatial resolution. In particular, the common counter allows to perform a fast preview mode, i.e. the common counter mode, which requires a high frame rate for the same data rate at a reduced resolution. This fast preview mode may be used for example for acquiring preview images in SEM or STEM, when a user wants to scan a number of image points very quickly.

Preferably, the detector comprises a configuration element for switching between the normal mode and the fast preview mode. The configuration element may in one embodiment be controllable by a user via a GUI, for example. The controllable configuration element, also referred to as switching element, preferably directs the input, i.e. digital pulses from the discrimination stage or the retrigger stage either to the local counter of the pixel, or to a counter common to a cluster of pixels. In a special scenario, this common counter may be represented by one of the local counters of the cluster.

Preferably, when the local counter of a pixel of the cluster serves as common counter in the fast preview mode, an element is provided collecting the pulses from the various pixels of the cluster. Such input element preferably is a multiple-input OR logic gate, where the output of all pixels of the clusters are connected to. The input element may be part of the pixel, or be provided outside the pixel. In the fast preview mode, the configuration element of each pixel of the set preferably connects through the output of the discrimination element or the retrigger unit to a common counting pixel output which is connected to the input element of the cluster. In the normal mode instead, the configuration element connects the output of the discrimination element or the retrigger unit to the local counter.

Especially in case that the local counter of a pixel of the cluster is designated as common counter, an output of the input element is connected via the configuration element to the local counter serving as common counter in case of the fast preview mode. The common counting pixel output of this pixel is also fed back to the input element.

In this fast preview mode, it is preferred that only the common counter of the cluster is enabled and read out, while the counters of the other pixels of the cluster are disabled. This aspect of the invention decreases the data per frame to be read out of the ASIC by up to a factor f=i×k corresponding to the number of pixels f in the cluster, which allows to increase the frame rate by up to this factor f. The pixels of a cluster are preferably neighboring pixels, e.g. 2×2, or 3×3.

The common counting pixel output stage may include a pulse-shortening circuit realized e.g. as differentiator stage. The pulse shortening circuit shortens the digital pulses coming from the local discrimination or retrigger stage—provided the configuration element is controlled into the fast preview mode for common counting—to a defined pulse length which is dimensioned rather short and as such prevents that comparator pulses from different pixels overlap in time when received by the input element within a very short time period. This would lead to a scenario, in which such pulses are not counted and the detection of corresponding events would be missed. An exception are the pulses from neighboring pixels caused by the same detection event, which do coincide precisely in time so that even their shortened pulses will overlap. This is desired as it assures that a single detection event does not cause more than one count (i.e. a statistically correct counting result). It is thus advantageous that the pulse shortening circuit produces pulses preferably shorter than 10 ns, 5 ns, 2 ns or 1 ns, and longer than 0.5 ns.

A combination of the input element, the configuration element and the pulse shortening element preferably is referred to as binning element. Accordingly, the binning element allows for a fast preview mode with pixel binning to reduce the pixels per image.

In case of n×m pixels in the sensor element and the ASIC, it is suggested to provide a readout logic for reading out the pixel counters in case of the readout circuits comprising counters. At the time of counter readout, the counter value preferably is transferred to a compression unit for compressing the information represented by the counter value. Such compression unit preferably is not part of the pixel readout circuit, but is represented by other circuitry, such as periphery circuitry. Accordingly, it is preferred that the number of compression units is less than the number of readout pixels, such that not all pixels can be readout and compressed simultaneously. Instead, it is envisaged that the number of compression units is equal to the number of columns (or to the number of rows) such that an individual compression unit is assigned to each column (or row) respectively. This implies, that in the first alternative, the pixels of a common row are read out simultaneously and the counter values are transferred to the assigned compression units, where the counter values are compressed. In a next step, the counter values of the next row are transferred simultaneously to the (same) compression units, where they are compressed.

The compression applied in the one or more compression units preferably is designed such that it preserves the relevant information of the counter values upon compression. The number of detection events in a pixel is of Poissonian nature with a noise level corresponding to sqrt{N}, where N is the mean number of detection events in the pixel at a given radiation or electron flux. A compression unit that introduces a relative compression error of less than sqrt{N}/N at counter value N thus preserves the relevant information of the counter.

In one embodiment, the compression applied to the counter value by the compression units is a compression complying with the IEEE floating point standard.

Preferably, the compression unit comprises a leading bit detector for determining the location of a leading bit of the counter value and an exponent generator for determining an exponent dependent on the position m of the leading bit and the bit depth l of the mantissa. Preferably, the leading 1 is suppressed in the float compression algorithm (like in the IEEE standard for binary floating point), thus saving one bit. Moreover, the compression preferably is implemented in a parallel way, i.e. each counter value fed to one of the readout columns is compressed in the compression unit within one readout clock cycle, for each readout column in parallel. Leading bit detection may be realized using combinatorial logic to generate the floating point representation within a single clock cycle.

In a preferred embodiment, to match the noise characteristics of Poissonian-distributed counter values the bit depth l of the mantissa equals ceil(n/2)−1 approximately half the size of the bit depth n of the input data, which can be the counter bit depth or the bit depth required to represent the maximum expected counter value.

As pointed out above, in particular 4D STEM may require high frame rates. In a plane of the sample, for example 20×20 up to 3000×3000 image points are scanned. For each image point, the detector records one frame. The higher the frame rate, the faster the scan can be performed. E.g. a high frame rate of 100 kHz with a frame size (number of ASIC pixels) of 192×192 pixels, and a bit depth of 12 bits results in a raw-data rate of 44 Gbps (Giga bit per second), a frame rate of 200 kHz frame rate in 88 Gbps. The above compression supports a reduction of data rates to be processed and transmitted.

In one embodiment, a partial readout of the ASIC pixel array is suggested. Accordingly, a region-of-interest is selected in a frame/an image while the detector allows for readout of only a corresponding part of pixels/rows. This procedure enables a proportionally higher frame rate.

In the following, features of further processing counter data in what is called a further readout chain are provided as preferred embodiments. Given that this processing may be implemented in circuitry inside the ASIC or outside the ASIC, the detector in combination with this circuitry is referred to as system.

Preferably, the system restores, i.e. converts back an integer count values from the binary float representation after transmission from the readout chip, before transmitting it to the user. For large count numbers, with a binary representation extending in length the bit depth of the mantissa (value of exponent e>=1), the conversion of the count value to a binary floating point number requires rounding. Typically, numbers will be rounded down to the nearest representable binary floating point number. This causes that the restored number will have an offset from the original count number on average over pixels in an image or over measurements of the same pixel to a lower value. For a given binary floating point number, this offset has an average value of −(2\hat{ }e)−1)/2, i.e.: 0, 0.5, 1.5, 3.5, . . . for e=0, 1, 2, 3, 4, . . . . This processing can be realized on a detector server (computer as part of the detector system) or specific hardware e.g. using FPGAs, GPU, embedded processor, . . . ).

Upon restoration of the count value the system may, in a preferred embodiment, automatically compensate for a rounding offset caused by the compression, e.g. by adding one additional lower bit with value “1” to the mantissa representation for e>=1, i.e. adding zero for e=0 and, adding 1, 2, 4, . . . for e=1, 2, 3, . . . to the binary number restored from the floating point value. This compensation of the average offset reduces the resulting average offset to +0.5 counts. To fully avoid systematic offset and obtain an average offset of zero counts, a random mechanism may be applied to add an additional count with 50% probability for each pixel readout.

According to a further embodiment, the system may also perform additional image processing operations on the data after transmission from the readout chip, before displaying to the user. These processing operations may include summing, compression, center of gravity calculation, Fourier transform, filter operations as e.g. noise filtering, spatial-frequency filtering such as high- or low-pass filtering or other spectral frequency filtering, summing over different regions of interest, e.g. summing the count values in one or a number of regions of the bright field (BF) region and in one or a number of different regions in the annular dark-field (ADF) region, and/or one or several regions in the high-angle annular dark-field (HAADF) region, binning, convolution, application of machine learning algorithms e.g. convolutional neural networks, general purpose neural networks, fully connected neural networks. This can allow to first, emulate the output of today's single or multi-element STEM detectors (e.g. with three possibly segmented detectors for bright field, annular dark field, and high-angle annular dark-field) to enable counting measurements compared to current measurements in today's multi-element detectors, second, additional binning to reduce the resolution, third, sum all counts to provide a flux measurement value. This allows for a significant reduction of data rate and correspondingly the amount of data to be stored from the measurement, and/or increasing the frame rate at the system output. The image processing may take place in the periphery of the ASIC, in specific hardware e.g. using a readout FPGA, GPU, embedded processor, or in a software running on a readout server.

Preferably, the system may provide feedback signals for alignment of the electron microscope at high speed, thereby enabling fast auto-alignment methods to be implemented.

The problem is further solved by a method of manufacturing a radiation detector. At least one sensor tile is provided with sensor material sensitive to the radiation. The sensor tile has a front side facing incident radiation, and a back side opposite the front side. On the back side of the sensor tile and in contact with the sensor material, multiple contacts are formed from electrically conducting material, thereby defining sensor pixels. On the front side of the sensor tile, a front electrode is formed. The forming of the front electrode and the forming of the contacts may be performed in any order. Additionally, at least one ASIC is provided with input contacts. The input contacts of the ASIC are electrically connected with the pixels of the sensor tile. At least one ASIC is provided comprising a set of readout circuits. Preferably, each readout circuit of the set comprises a counter. The contacts of the sensor element are electrically connected to the readout circuits for enabling each readout circuit to process a signal received from the sensor pixel the readout circuit is electrically connected to, which processing preferably includes counting pulses representative of the radiation incident in the corresponding sensor pixel.

In a preferred embodiment, a braking layer is formed on the front electrode by monolithic integration, i.e. the material of the braking layer is directly applied onto the front electrode absent any prefabrication into sheets. Monolithic integration may include one of spin coating, magnetron sputtering or thermal evaporation. Subject to the thickness and choice of material, the formation in particular of thick braking layers may require special deposition processes. The formation of a thick beryllium braking layer preferably is conducted by a magnetron sputtering process. The formation of a thick Diamond or DLC braking layer preferably is achieved by growing thick layers by e.g. PECVD.

In particular when monolithic integration processes are used for depositing both the braking layer and the front electrode, it is preferred that both are manufactured in a common process step with the same material. In an area of the sensor tile where the braking effect is desired to be achieved the material preferably is deposited at a thickness of at least 5 μm. Such area may represent only a partial or limited area of the sensor tile, while in the remaining area the material may be deposited at a lower thickness.

In a different embodiment, the braking layer is formed by a silicon based wafer bonded onto the front electrode by room temperature wafer-to-wafer bonding. In a further embodiment, the braking layer is formed by a GaAs wafer which may be applied by low temperature direct wafer bonding via plasma activation. In a different embodiment, the braking layer is made from or comprises an organic resist compound like SU8 and is spin coated up to a thickness of e.g. 450 microns onto the front electrode.

In a different embodiment, the braking layer is prefabricated in form of a sheet, which sheet is applied onto the front electrode by adhesion, preferably by using an adhesion layer or by self-adhesion of the braking layers.

According to another aspect of the present invention, an electron microscope is provided, comprising a source for generating an electron beam, and a sample holder for exposing a sample to be investigated to the electron beam. A radiation detector according to any of the preceding embodiments is arranged to detect electrons transmitted through or scattered by the sample when arranged in the electron beam.

In one embodiment, the radiation detector is movable in and out of the electron beam, preferably in a retractable way. Also the sample holder preferably is movable in and out of the electron beam, preferably in a retractable way. The source of the electron beam preferably is an electron gun.

Preferably, the electron microscope comprises a so-called column, i.e. a high vacuum volume confined by a e.g. cylindrical vacuum chamber. Preferably a part of the detector, e.g. at least the sensor, the ASIC, and a circuit board for supporting the ASIC, is arranged inside the electron microscope's column, and hence in a vacuum environment, with a high amount of ionizing radiation such as beta or electron radiation, or gamma radiation originating e.g. from bremsstrahlung produced by electrons hitting parts of the microscope or the detector. Other elements of the detector are preferably arranged outside the electron microscope's column. Preferably, the inside and the outside part are separated by a radiation shield in order to prevent radiation to leak. Furthermore, in order to prevent leakage of the vacuum, the parts inside and outside are preferably separated by a vacuum seal.

Preferably, the electron microscope is a 4D-STEM device. However, in different applications, the electron microscope generally is a Transmission Electron microscope (TEM), or a Scanning Transmission Electron microscope (STEM). In other embodiments, the electron microscope is one of an Annular Dark-Field STEM (ADF STEM) device, a High-Angle Annular Dark-Field STEM (HAADF-STEM) device, a Bright-Field STEM (BF STEM) device, a High-Resolution STEM (HRSTEM) device, a Differential Phase-Contrast STEM device or a Time-Resolved TEM device. Other electron microscopy techniques for which the electron microscope may be applied include Electron diffraction (ED), in particular Backscattering Electron Diffraction (BSED or EBSD), Convergent Beam electron diffraction (CBED), Micro electron diffraction (MicroED), Nano-Beam Diffraction (NBD), Precession electron diffraction, Selected area electron diffraction (SAED). Or Environmental TEM (ETEM), Energy-Filtered TEM (EFTEM), In-situ TEM, Electron energy-loss spectroscopy (EELS), Elemental mapping, Ptychography, or Transmission-SEM.

Any of these EM techniques benefit from a very fast detector with high count rate.

The radiation detector may also be applied in X-ray detection and be especially useful in any applications which benefit from a fast frame rate such as highspeed X-ray imaging applications and X-ray computed tomography (CT) both in medical, industrial or security applications, and for recording X-ray diffraction patterns e.g. in X-ray ptychographic imaging, coherent diffractive imaging, X-ray photon correlation spectroscopy, and any time-resolved or fast-scanning X-ray diffraction such as time-resolved powder X-ray diffraction or powder X-ray diffraction CT. The detector may also be applied in X-ray spectroscopy including X-ray plasma spectroscopy. The radiation detector is especially advantageous when using intense X-ray sources leading to high count rates per pixel, which sources can be synchrotron radiation sources, liquid metal jet X-ray sources, rotating anode X-ray sources, but also X-ray laboratory equipment using conventional X-ray tubes, either of these using the direct X-ray beam or in combination with filter(s) and/or monochromator device(s). Moreover, the present fast imaging or tracking radiation detector may also be used in radiation therapy using high-energy photons or particle radiation for monitoring the position of the therapy beam and/or the patient position.

The invention allows, in particular when applied to 4D STEM, to scan a field of view of e.g. 32×32 image points or 64×64 image points or 1024×1024, or more, with a dwell time of typically below 5 μm, 10 μm, 20 μm. For each image point, an image with the HPD is recorded, and frame rates of above 200 kHz can be achieved. Hence, STEM images can be generated at high temporal and/or spatial resolution, which is supported e.g. by a compression of the count values in order to optimally use the limited data transfer rate out of the ASIC, and/or e.g. by a fast preview mode with pixel binning to reduce the pixels per image. Preferably, a sufficient bit depth of the counter in the readout circuit allows to count above 100 or above 1000 or above 10000 or above 100000 or above 1M detection events per frame, which prevents a counter overflow.

Sensor degradation possibly caused by high-energetic electrons displacing lattice atoms in the sensor material can be minimized by the braking layer. Preferably, to counteract the slight degradation of spatial resolution and efficiency caused by the braking layer, an adjustable energy threshold is adjusted to optimize imaging performance of the detector for a given application (EM device) either for optimal spatial resolution and count rate characteristics, or, efficiency.

The detector may cope with high incoming electron fluxes and rates, such as up to 20 pA/pixel, corresponding to about 120,000,000 electrons/pixel/s, with a minimal pile-up effect in the counting pixel circuit in the ASIC. It is preferred to use an amplifier in the readout circuit of each pixel with a short shaping time, and it is preferred to make use of a retrigger unit as described above.

The fast framing detector is also beneficial to overcome degradation of the measurement caused by drift of the sample or the electron beam.

### BRIEF DESCRIPTION OF THE DRAWINGS

The invention will be better understood and objects other than those set forth above will become apparent when consideration is given to the following detailed description thereof. Such description makes reference to the annexed drawings, wherein the Figures illustrate:

FIG. 1 a schematic cut view of a radiation is detector implementing hybrid pixel detection (HPD), according to an embodiment of the present invention;

FIG. 2 the sensor element of FIG. 1 in an enlarged view;

FIG. 3 a different embodiment of a sensor element, according to an embodiment of the present invention;

FIG. 4 a different embodiment of a sensor element, according to an embodiment of the present invention;

FIG. 5 a graph showing the effect of the means illustrated in FIGS. 1 to 4 for decelerating the electron beam;

FIG. 6 a block diagram of a readout pixel comprised in an ASIC, according to an embodiment of the present invention;

FIG. 7 a block diagram of another readout pixel comprised in an ASIC, according to an embodiment of the present invention;

FIG. 8 a block diagram of a cluster of readout pixels 23 comprised in an ASIC, according to an embodiment of the present invention;

FIG. 9 a more detailed block diagram of the binning element of the readout pixel of FIG. 7;

FIG. 10 a schematic layout of a readout ASIC in top view, according to an embodiment of the present invention;

FIG. 11 a schematic layout of another readout ASIC in top view, according to an embodiment of the present invention;

FIGS. 12 and 14 more detailed block diagrams of circuitry as used in the embodiments of FIG. or FIG. 11, and

In FIG. 13, a table describing the compression algorithm as applied in a compression unit of an ASIC, according to an embodiment of the present invention.

### MODES FOR CARRYING OUT THE INVENTION

Same elements are referred to by the same reference numerals across all Figures.

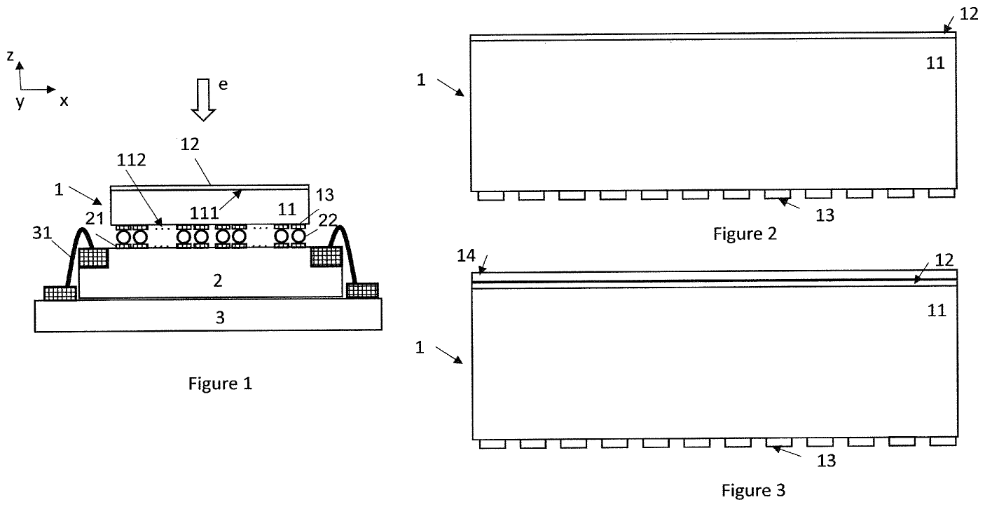

FIG. 1 illustrates a radiation detector implementing hybrid pixel detector (HPD) technology according to an embodiment of the present invention. The detector comprises a sensor element 1 that is supported by and is electrically connected to a CMOS readout ASIC 2. The ASIC 2 in turn is supported by and electrically connected to a circuit board 3, e.g. by means of bond wires 31.

The sensor element 1 has a sensor in form of a tile 11 comprising or consisting of a sensor material suitable to convert incident X-rays/electrons—indicated by arrow e—into an electric charge. As sensor material, silicon, or a high-Z material like gallium arsenide (GaAs), cadmium telluride (CdTe), cadmium zinc telluride (CZT), mercury iodide (HgI), perovskites, or others can be used. The sensor tile 11 has a planar extension in x- and y-direction.

A front electrode 12 is arranged on a front side 111 of the sensor tile 11. Any signals created by the incoming radiation created inside the front electrode layer will not be collected and are thus lost. Thus, the front electrode forms a dead layer. The front electrode 12 may comprise one or multiple thin layers of metal. In the latter scenario, the front electrode 12 preferably consists of a stack of materials, formed e.g. from aluminium, gold, platinum or other metals.

In order to be able to collect the large amount of created charges due to the high incoming radiation current and its high energy, a bias voltage creating an electric field of at least 300 V/mm sensor thickness preferably is applied to the front electrode.

On a back side 112 of the sensor tile 11, pixelated electrical contacts 13 are provided, which transmit the electrical signal to the readout ASIC 2. Each one of the contacts 13, also referred to as back contacts 13, is connected to the corresponding contact 21 of the readout ASIC 2 by means of bump bonds 22. Assignments between contacts 13 and contacts 21 other than 1:1 are possible.

Readout circuits in the ASIC 2 first collect at their contacts 21 the charge from the corresponding sensor pixel, amplify this signal in an amplifier stage, apply an adjustable threshold in a comparator to the amplified signal and count the thresholded signals—preferably digital pulses at the comparator output—within a defined interval. Once the interval is terminated, the counter values are read out and send serially or in parallel to a readout board.

In conventional radiation detectors, the front electrode 12 is thin, with a thickness in z-direction of less than 1000 nm, below 500 nm or below 100 nm. The small thicknesses are chosen in order to have a high sensitivity to detect incoming electron radiation and to lose as little incoming charge as possible. Owing to the small thickness of the front electrode, it has no significant effect on (contribution to the braking of) 200 keV-300 keV electrons, and only serves as an electrical contact layer needed to apply a bias voltage to the sensor.

FIG. 2 illustrates sensor element 1 of FIG. 1 in an enlarged view.

FIG. 3 illustrates a different embodiment of a sensor element 1 according to an embodiment of the present invention. In this embodiment, a braking layer 14 is arranged on top of the front electrode 12. Preferably, the braking layer 14 is formed by monolithic integration, i.e. is directly applied onto the front electrode 12, e.g. by way of spin coating, magnetron sputtering or is thermal evaporation. The braking layer 14 preferably comprises or consists of a low-Z metal, such as aluminium, added at least partially in an area larger than 10×10 pixels and/or 5 mm² on top of the front electrode 12 with a preferred thickness of 5 μm, 10 μm, 15 μm, 20 μm or above 50 μm. Subject to the thickness and choice of material, the formation in particular of thick braking layers may require special deposition processes. The formation e.g. of a thick metallic braking layer of beryllium preferably is conducted by a special magnetron sputtering process, as is described e.g. in “Thick beryllium coatings by ion-assisted magnetron sputtering”, Journal of Material Research, H. Xu et al, 27, 5 pp 822 (2012), or in “Progress toward fabrication of graded doped beryllium and CH capsules for the National Ignition Facility”, A. Nikroo, K. C. Chen, M. L. Hoppe, H. Huang, J. R. Wall, and H. Xu Physics of Plasmas 13, 056302 (2006). In a different embodiment, the monolithic integration of e.g. diamond or DLC layers on the sensor is opened by the possibility of growing thick carbon based layers by e.g. PECVD on top of semiconductor materials. A good description of the state of the art of this particular coatings is summarized in “A review of nucleation, growth and low temperature synthesis of diamond thin films” Materials Reviews (2007), D. Das and R. N. Singh. In a further embodiment, room temperature wafer-to-wafer bonding can be used to integrate a thick silicon braking layer of silicon on top of a high-Z sensor. E.g. low temperature direct wafer bonding of GaAs to Si via plasma activation can be applied, see C. Y. Yeo, D. W. Xu, S. F. Yoon, and E. A. Fitzgerald, Appl. Phys. Lett. 102, 054107 (2013). In a different embodiment, a braking layer made from or comprising an organic resist compound like SU8 may be spin coated up to a thickness of e.g. 450 microns onto the front electrode 12, e.g. by way of a process as described in H Lorenz, M. Despont, N. Fahrni, N. Labianca, P. Renaud and P. Vettiger J. Micromech. Microeng. 7 (1997) 121-124.

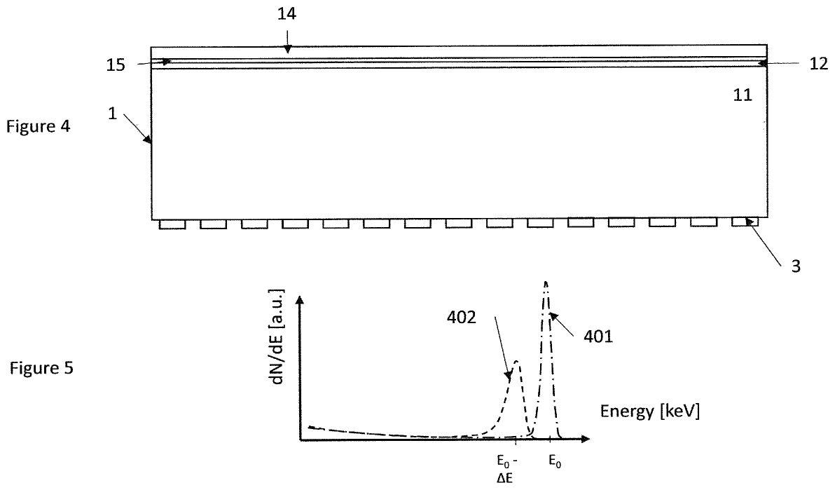

FIG. 4 illustrates a different embodiment of a sensor element 1 according to an embodiment of the present invention. In this embodiment, a braking layer 14 is arranged at least partially in an area larger than 10×10 pixels and/or 5 mm² on top of the front electrode 12 by means of an adhesive 15. Accordingly, preferably a prefabricated braking layer 14 in form of a sheet of low-Z material, e.g. comprising or consisting of beryllium, aluminium, an organic compound, with a thickness of preferably above 10 μm, 50 μm, 100 μm or 200 μm is attached by means of the adhesive 15 to the sensor tile 11, covering at least a part of the top electrode.

In the embodiments of FIG. 3 and FIG. 4, the braking layer 14 may also be conductive and a connection to the top electrode 12 preferably is conductive. Thus, the bias voltage can be connected to the braking layer 14 e.g. by means of a low resistivity wire bond, cable, wire or conductive adhesive layer. In a different embodiment, the braking layer 14 does not cover the whole front electrode 12, and the bias voltage connection is done directly to the front electrode 12, by means e.g. of a low resistivity wire bond, cable, wire, conductive adhesive layer. In a different embodiment, a conductive adhesive layer extending out from the assembly of sensor and braking layer is used to establish the bias voltage connection. Hence, in these embodiments, the braking layer 14 or the adhesive 15 are preferably used to connect to a high-voltage source.

FIG. 5 illustrates the effect of the means illustrated in FIGS. 1 to 4 for decelerating the electron beam at hand of electron-energy spectra. The abscissa denotes the electron energy in keV while the ordinate denotes dN/dE. Electrons in the electron beam with energy E₀ deposit energy according to spectrum 401 to the sensor element 1. If a braking layer 14 is applied on top of the front electrode 12, a part of the energy of the incoming electrons is deposited in the braking layer 14. Thus the total energy deposited in the sensor element 1 is E₀-ΔE, compared to E₀ without braking layer 14. The corresponding spectrum 402 is illustrated in FIG. 4.

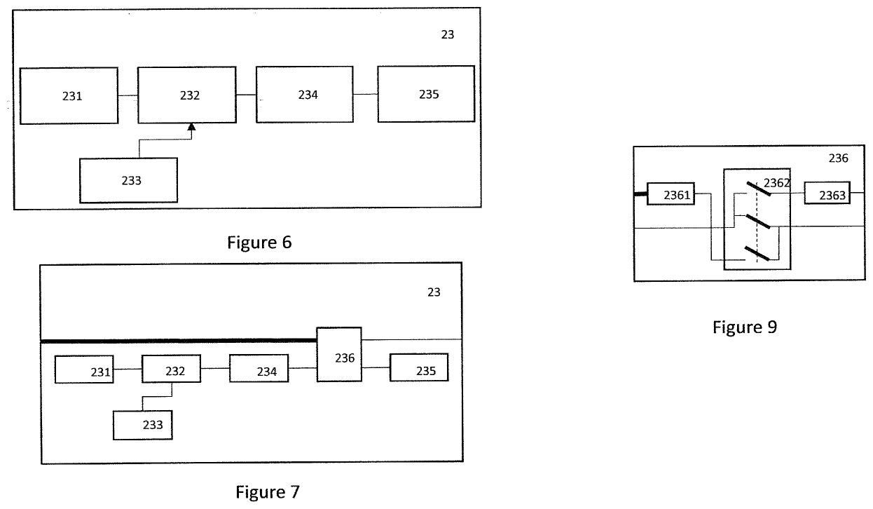

FIG. 6 illustrates a block diagram of a readout pixel 23 comprised in an ASIC representing its core functions, according to an embodiment of the present invention. With reference to FIG. 1 again, the charge created in the sensor material of the sensor element 1 drifts through the sensor tile 1 to one or several pixel contacts 13. Each pixel contact 13 is connected by means of bump bonding 22 to one ASIC pixel 23. According to FIG. 6, the charge enters the amplifier stage 231, which converts the created charge to a voltage pulse. To allow for a high incoming electron rate, the amplifier stage 231 preferably is designed to be able to create very short pulses with a FWHM pulse duration between 5 ns-500 ns, and more preferably with a FWHM pulse duration advantageously chosen to be shorter than 40 ns, 20 ns or ns. The amplifier stage 231 is followed by a fast discrimination stage 232, where the voltage pulses are discriminated. Pulses with a voltage above a threshold will be converted to a digital pulse, with a pulse length corresponding to the duration of the analog pulse voltage being above the threshold voltage. Pulses not exceeding the threshold do not make it to the output of the discrimination stage 232. Accordingly, in the fast discrimination stage 232 the voltage pulses are compared to the threshold. A threshold generation unit 233 is provided for determining the threshold. The threshold preferably is determined subject a global voltage applied to the ASIC combined with an individual trimming per pixel.

To prevent counting paralyzation due to pulse pile-up at high rates, a retrigger unit 234 is used. The retrigger unit 234 preferably can be disabled or enabled by the user. An adjustable retrigger duration is advantageously matched to the analog voltage pulse duration, where the analog voltage pulse duration is defined as the duration the analog pulse spends above the threshold voltage. In a preferred embodiment, the retrigger duration is set to be slightly longer than the analog pulse duration, e.g. by 2 ns, 5 ns, 10 ns or 20 ns longer than the analog pulse duration. Hence, instant retrigger technology re-evaluates the pulse signal after a predetermined retrigger duration after each count and potentially retriggers the counting circuit in case of pulse pile-up.

In subsequent linear counting unit 235, also referred to as counter, each pulse created at the output of the retrigger stage 234 increases the counter in the counting unit by one. Preferably, the counting unit 235 comprises at least two counters that can be switched between subsequent exposures and allow for continuous (deadtime-free) readout reading one of the counters while the other one is active for counting.

FIG. 7 illustrates a block diagram of another readout pixel 23 comprised in an ASIC, according to an embodiment of the present invention, and introducing a very preferred feature over the embodiment shown in FIG. 6.

Subsequent to the retrigger unit 234 and before the counter 235, a binning element 236 is provided. The binning element 236 either passes the output of the retrigger stage 234 directly to the pixel counter 235, or, to a common counter of a pixel cluster. Accordingly, each pixel may count for its pulses stand alone, and/or a common counter may be provided to accumulate the counts of a number of i×k pixels. Of course, pulses from a pixel may be counted individually by the pixel counter. In an alternative configuration, the pulses stemming from a number of neighboring pixels are accumulated in the common counter. The common counter may be an individual counter in addition to the counters of the pixels of the cluster, or one of the counters of the cluster pixels may be used for accumulating the pulses from all of the cluster pixels. Accordingly, it is preferred that either the pulses of a pixel are counted individually, or the pulses of several pixels of a cluster are accumulated. In particular, these two modes may be set by the user, and corresponding settings may be taken at the binning elements 236 of the pixels.

The reason for a common counter for a pixel cluster may lie in an enormous frame rate of up to several 100 kHz required for fast electron-beam scanning to obtain STEM images at high temporal and/or spatial resolution, which concept supports very high frame rates at the cost of resolution. In another scenario, the detector may support such high frame rates, however, it is desired to provide a fast preview mode which requires an even higher frame rate for the same data rate, again at a reduced resolution of the frame. This fast preview mode may be used for example for acquiring preview images in SEM or STEM, when a user wants to scan a number of image points very quickly, and thus requires an even higher frame rate.

Preferably, it can be switched between a normal mode with counts per pixel at pixel resolution and a standard frame rate, and a fast preview mode with counts per cluster of pixels, i.e. at a lower resolution than per pixel, however at a higher rate than the standard frame rate. In this fast preview mode, it is preferred that only the common counter of the pixel cluster is enabled and read out, while the counters of the other pixels of the cluster are disabled. This aspect of the invention decreases the data rate to be read out of the ASIC by up to a factor f=i×k corresponding to the number of pixels in the cluster, which allows to increase the frame rate by up to this factor f.

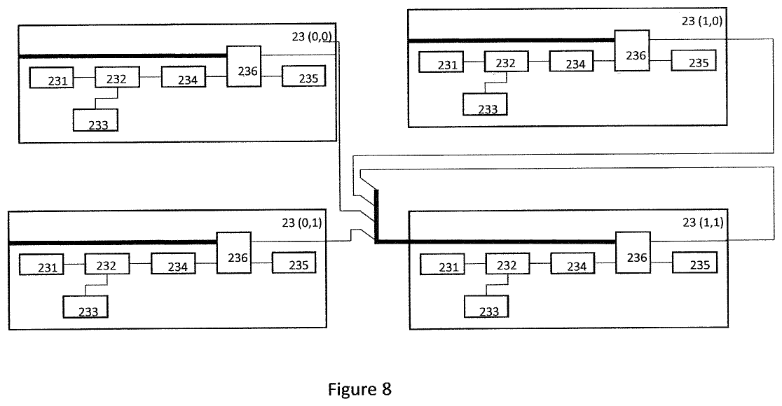

FIG. 8 illustrates a block diagram of a cluster of readout pixels 23 comprised in an ASIC, according to an embodiment of the present invention. The cluster presently includes four pixels arranged i=2×k=2, each according to the block diagram of FIG. 7. As can be derived from FIG. 8, the outputs of the binning elements 236 of the individual pixels for common counting are led to the input of the binning element 236 of the fourth pixel (1,1) and are counted there by counter 235 serving as common counter. The counters 235 of the other pixels (0,0) (1,0), (0,1) are disabled.

In a different embodiment, the digital signals after the retrigger stage 234 can be fed to a common counter provided outside the readout circuits 23 involved, and hence in addition to the counters 235 provided in the readout circuits 23. The common counter may support counting the pulses from f pixels with f>1. In particular, a cluster may contain of i×k pixels, for example of 2×2 pixels or 2×1 pixels or 3×3 pixels.

FIG. 9 illustrates a block diagram of a binning element 236 as used in the ASIC of the previous Figures in more detail. The binning element 236 may be configured into pixel counting or cluster counting via a configuration element 2362. The configuration element 2362 may be controlled, e.g. by user input, into the present state, where an input from the retrigger element of the present pixel is interconnected with the output to the local counter. The output leading to the common counter is disconnected from any input by means of the configuration element. Hence, this state represents the normal mode in which the pulses of a pixel are counted locally, per pixel.

In the alternative state of the configuration element 2362, again e.g. controlled by user input, the input from the retrigger element of the present pixel is now interconnected with element 2363 which output leads to the element 2361 of the pixel with the common counter. On the other hand, the input via element 2361 now is connected to the local counter 235. Given that the element 2361 represents a multiple input OR logic gate with an is input for each of the pixels of the cluster—including the one from the present pixel i.e. the output at 2363, the pulses stemming from all pixels of the clusters are now led to the counter of the present pixel which accordingly acts as a common counter for the number of pixels in the cluster. Obviously, the element 2361 and any wiring thereto can alternatively be omitted in any pixels not required/connected for common counting.

Element 2363 represents a pulse-shortening circuit realized e.g. as differentiator stage. According to the arrangement of the pulse shortening circuit, and subject to the state of the configuration element 2362, it shortens the digital pulses coming from the local retrigger stage and as such prevents that comparator pulses from different pixels overlap in time when received by the corresponding pixels within a very short time period. This would lead to a scenario, in which such pulses are not counted and the detection of corresponding events would be missed. An exception are the pulses from neighboring pixels caused by the same detection event, which do coincide precisely in time so that even their shortened pulses will overlap. This, in this case is desired as it assures that a single detection event does not cause more than one count, whereby a statistically correct counting result is achieved. It is thus advantageous that the pulse shortening circuit produces pulses shorter preferably than 10 ns, 5 ns, 2 ns or 1 ns, and longer than 0.5 ns.

Accordingly, the binning element allows for a fast preview mode with pixel binning to reduce the pixels per image.

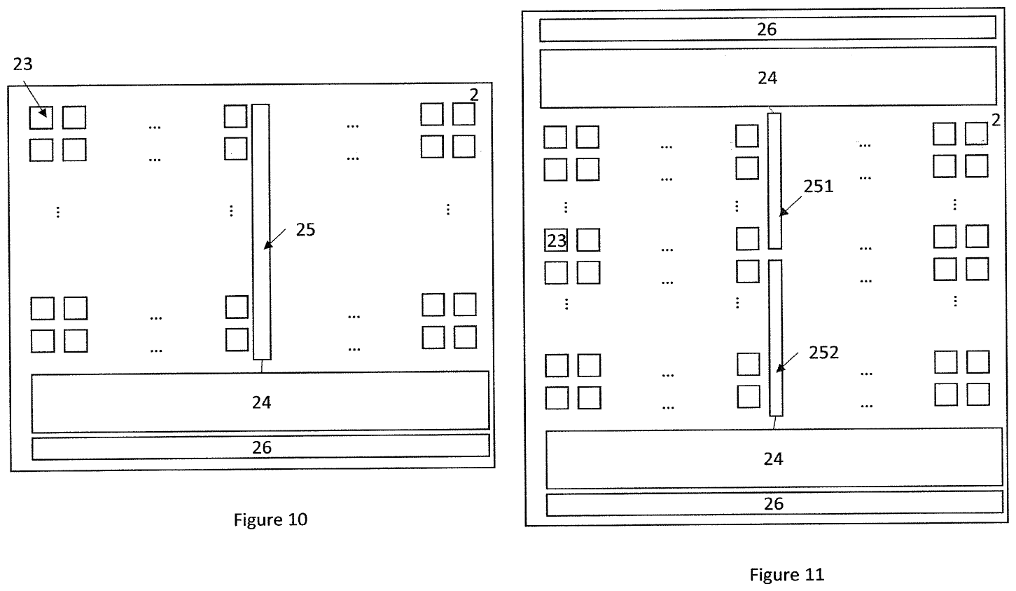

FIG. 10 shows a schematic layout of a readout ASIC 2, e.g. in top view. Readout circuits 23—also referred to as ASIC pixels 23—are arranged in an array of m rows and n columns. The ASIC pixel array may e.g. comprise 128×128 pixels, or 192×192 pixels, or 256×256 pixels, e.g. with a pixel pitch between 25 μm and 500 μm.

In the bottom, circuitry 24 is provided for processing counter values of the counters 235 of the ASIC pixels 23. A row control 25 allowing to select at least one row of the array may be used to connect each ASIC pixel 23 of the selected row to a column data receiver in the circuitry 24 via a read out bus.

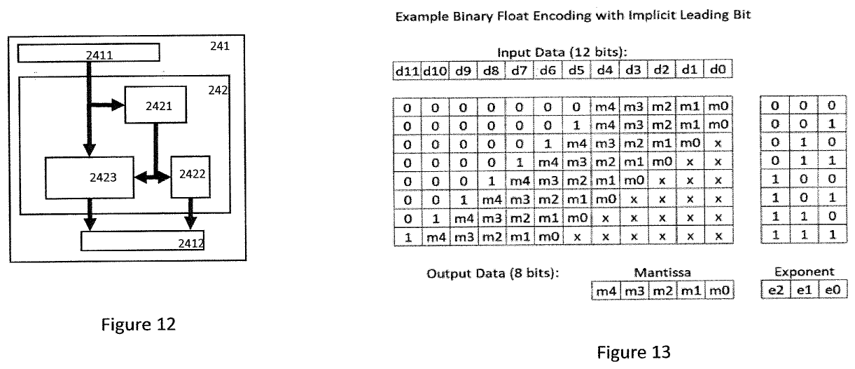

In this embodiment, the circuitry 24 comprises m processing units 241. A block diagram of a processing unit 24 is illustrated in FIG. 12. The processing unit 241 comprises a column data receiver 2411 for temporarily buffering the counter value received from the counter of the corresponding ASIC pixel. The column data receiver 2411 is connected to a compression unit 242. The compression unit 242 comprises a leading bit detector 2421 for determining the location of a leading bit of the counter value. The leading bit detector 2421 may work along the following lines:

Let the integer number m in the range 0 . . . n−1 describe the position of the leading bit in the n bits of the counter, where the position m is counted starting from the least significant bit (LSB) at m=0. Depending on the location of the leading bit m and the bit depth l for the mantissa, the multiplexer bank (202) selects the l bits to be used as mantissa: For the case (m+1)>l the bits at the positions m−l to m−1, for the case (m+1)<=l the least significant bits at positions m=0 to m=(l−1). The selected bits are multiplexed to the mantissa region in a data output latch 2412.

An exponent generator 2422 determines the exponent dependent on the position m of the leading bit and the bit depth l of the mantissa, for the case (m+1)>l the exponent is set to m+1−l, and, for the case (m+1)<=l the exponent is set to 0. The exponent determined by the exponent generator 2422 in binary representation is set on the exponent region of the data output latch 2412. The bit depth of the exponent is ceil(log 2(n+1−l)) where the function ceil rounds its argument to the next higher integer value, which is the minimum bit depth of the exponent required to cover the full value range of an n-bit counter. In some applications or measurements it may be useful to use less bits for the mantissa and/or the exponent, e.g. where the full counter bit depth is not needed, i.e. the counter is not filled during the exposure time, the bit depth of the exponent or mantissa may be accordingly smaller.

In FIG. 13, a table describes the compression algorithm as applied in a compression unit of an ASIC, according to an embodiment of the present invention. In this embodiment, it is assumed that the counter provides 12 bit values presently denoted as d0 to d11. Accordingly, the bit depth of the counter values is n=12 which is compressed to 8 bits, with a bit depth l=5 of the mantissa, and a bit depth 3 for the exponent. The leading bit with value ‘1’ is suppressed in the mantissa, as it is encoded by the value of the exponent.

Back to FIG. 12, in the compression unit 242, a multiplexer bank 2423 may be provided. The multiplexer bank 2423 may be configured to bypass the compression unit and directly pass the counter value to the data output latch 2412 without compression.

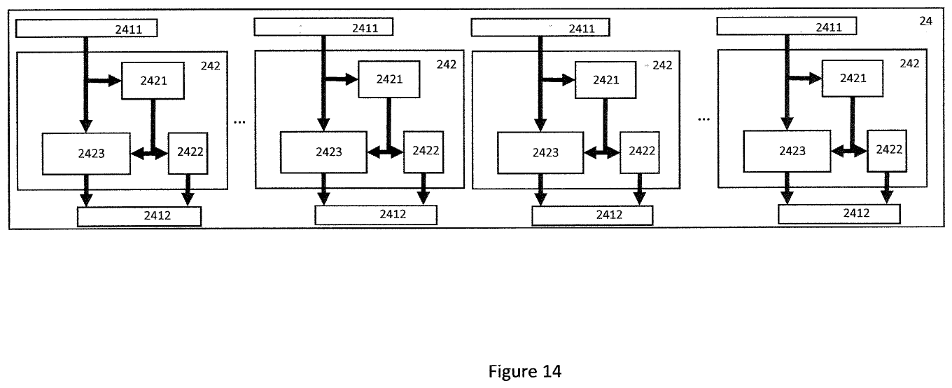

FIG. 14 illustrates circuitry 24 of FIG. 10 in more detail. Accordingly, m processing units are used, one per column.

Referring back to FIG. 10, after compression, the compressed counter values are available at ASIC input/output contacts 26 of the ASIC 2 for digital and analog input and output signals, which connect to a detector readout system.

FIG. 11 shows another embodiment of the invention. Here the column readout bus of FIG. 10 is split in two column read out busses 251 and 252 with dedicated row controls, now responsible for half the rows. Accordingly, ASIC pixels 23 are read out via input/output contacts 26 at two sides of the ASIC 2, and circuitry 16 including compression units may be arranged at two sides of the ASIC 2, too. This allows in a simple way to double the frame rate capability of the pixel array.

In a further embodiment of the invention, the input/output contacts 26 and/or the circuitry 24 may be distributed around all four sides of the ASIC. This allows for more data output pads and increases thus the data throughput rate and thus the frame rate.

While there are shown and described presently preferred embodiments of the invention, it is to be distinctly understood that the invention is not limited thereto but may be otherwise variously embodied and practiced within the scope of the following claims.

1. Radiation detector for position-resolved detection of radiation, comprising
at least one sensor tile with a front side facing incident radiation, and a back side opposite the front side, the sensor tile comprising sensor material sensitive to the radiation,
a front electrode arranged on the front side of the sensor tile,
a set of contacts of electrically conducting material arranged on the back side of the sensor tile and in contact with the sensor material, thereby defining sensor pixels,
a braking layer arranged on and at least partly covering the front electrode, for decreasing energy or flux of the incident radiation,
at least one ASIC comprising a set of readout circuits in electrical connection with the contacts, each readout circuit being configured to process a signal received from the sensor pixel the readout circuit is electrically connected to,
wherein each readout circuit of the set is configured to provide an output signal representative of the radiation incident in the corresponding sensor pixel.

2. Radiation detector according to claim 1, wherein the sensor material comprises or is made from a high-Z material, with Z>30.

3. Radiation detector according to claim 1,
wherein the braking layer covers an area of the front electrode of at least 10×10 sensor pixels or at least 5 mm².

4. Radiation detector according to claim 1,
wherein the braking layer is configured to decelerate electrons in the incident radiation, and
wherein the braking layer comprises or is made from a low-Z material, with Z<23.

5. Radiation detector according to claim 1,
wherein a thickness of the braking layer is equal to or exceeds 1 μm.

6. Radiation detector according to claim 1,
wherein the braking layer is made from the same material as the front electrode,
wherein a combined thickness of the braking layer and the front electrode is at least 5 μm within an area of the front electrode covered by the braking layer.

7. Radiation detector according to claim 1,
wherein each readout circuit of the set comprises a counter for counting pulses generated in the corresponding sensor pixel in response to the radiation incident thereto, and is configured to provide the output signal subject to the counted pulses.

8. Radiation detector according to claim 7,
wherein at least two readout circuits of the set comprise a configuration element for activating a common counting of the pulses from the at least two readout circuits,
wherein, when activated by the configuration element, one of the counters of the at least two readout circuits is connected to count pulses from the at least two readout circuits.

9. Radiation detector according to claim 8, comprising
for each of the at least two readout circuits, an element configured to shorten a duration of the pulses supplied by the readout circuit for the common counting.

10. Radiation detector according to claim 1,
wherein the ASIC comprises at least one compression unit connectable to the or a subset of the readout circuits of the set configured to compress a counter value read out from the counter of the connected readout circuit.

11. Radiation detector according to claim 10,
wherein n×m readout circuits of the set are arranged in the ASIC in form of an array,
wherein a number of compression units in the ASIC at least equal to the number m of readout circuits arranged in a row of the array,
wherein the ASIC comprises a row control for transferring counter values from the readout circuits of a row to the corresponding compression units,
wherein the compression units are configured to operate in parallel in compressing the transferred counter values.

12. Electron microscope, comprising
a source for generating an electron beam,
a sample holder for holding a sample to be investigated in the electron beam, and
a radiation detector according to any of the preceding claims, arranged to detect electrons transmitted through or scattered by the sample when arranged in the electron beam,
wherein the electron microscope is a 4D-STEM device.

13. Method of manufacturing a radiation detector, comprising the steps of
providing at least one sensor tile with sensor material sensitive to the radiation, the sensor tile extending in a planar dimension with a front side facing incident radiation, and a back side opposite the front side,
forming multiple contacts of electrically conducting material on the back side of the sensor tile in contact with the sensor material, thereby defining sensor pixels, forming a front electrode on the front side of the sensor tile,
forming a braking layer on the front electrode covering at least 10×10 sensor pixels or at least 5 mm2 of the front electrode,
providing at least one ASIC comprising a set of readout circuits,
electrically connecting the contacts with the readout circuits for enabling each readout circuit to process a signal received from the sensor pixel the readout circuit is electrically connected to.

14. Method according to claim 13, wherein the braking layer is formed on the front electrode by one of spin coating, magnetron sputtering or thermal evaporation.

15. Method according to claim 13, comprising attaching the braking layer in form of a sheet on the front electrode by adhesion, preferably by using an adhesion layer or by self-adhesion of the braking layer.

16. Method according to claim 13, comprising attaching the braking layer in form of a silicon based wafer on the front electrode by wafer-to-wafer bonding.

17. Method according to claim 13,
wherein the braking layer is made from the same material as the front electrode,
wherein the front electrode and the braking layer are formed by the same manufacturing method, and
wherein the braking layer and the front electrode are formed to a combined thickness of at least 5 μm.

18. Radiation detector according to claim 5, wherein the thickness of the braking layer, and more preferably is equal to or exceeds 5 μm.

19. Radiation detector according to claim 9, wherein the element is configured to shorten a duration of the pulses supplied by the readout circuit to less than 10 ns, preferably less than 5 ns, preferably less than 2 ns or preferably less than 1 ns, and/or preferably more than 0.5 ns.

20. Radiation detector according to claim 11, wherein the element is configured to be only activated in case of the configuration element being activated.
